(19) United States
(12) Patent Application Publication
(10) Pub. No.: US 2005/0240848 A1
(43) Pub. Date: Oct. 27, 2005

(54) Masking circuit and method of masking corrupted bits

(75) Inventors: Jean-Francois Cote, Chelsea (CA); Paul Price, Stoughton, MA (US); Benoit Nadeau-Dostie, Gatineau (CA)

Correspondence Address: LOGICVISION (CANADA), INC., 1565 CARLING AVENUE, SUITE 508, OTTAWA, ON, K1Z 8R1, CA

(73) Assignee: LogicVision, Inc., San Jose, CA (US)

(21) Appl. No.: 11/109,844

(22) Filed: Apr. 20, 2005

Related U.S. Application Data
(60) Provisional application No. 60/564,211, filed on Apr. 22, 2004.

(51) Int. Cl. G01R 31/28

(52) U.S. Cl. 714/726

(57) ABSTRACT

A masking circuit for selectively masking scan chain inputs and/or outputs during scan testing of an integrated circuit, comprises a mask register having at least two mask register elements for each scan chain to provide a plurality of masking modes; and an input and output mask control circuit for each scan chain, each mask control circuit being connected between a test pattern source and a signature register and between a serial input and a serial output of an associated scan chain and being responsive to mask control data stored in the register elements for configuring the associated scan chain in one of the plurality of masking modes during a scan test of the circuit.

### CROSS-REFERENCE TO RELATED APPLICATIONS

This application claims the benefit of U.S. Provisional Patent Application Ser. No. 60/564,211 filed Apr. 22, 2004, incorporated herein by reference.

### BACKGROUND OF THE INVENTION

1. Technical Field

The present invention generally relates to testing of integrated circuits and, more specifically, to a method of performing signature analysis in the presence of corrupted bits.

2. Description of Related Art

Integrated circuits are now commonly designed with scan chains comprised of a plurality of scannable memory elements or scan cells. Each scan chain has a serial input for serially loading a test pattern into the scan chain and a serial output connected to a signature register through a masking circuit, described later. Memory elements which form the scan chains are connected to combinational logic circuits. During a scan test of a circuit, test patterns are loaded into the memory elements by shifting them through the serial inputs and then applying the test patterns to the combinational logic circuits. The response of the combinational circuits is then captured by the memory elements and unloaded by shifting out the contents of the memory elements and applying the responses to the inputs of a signature register which generates a signature.

Combinational circuits are typically designed so that the response of the circuits is predictable and repeatable. That is, the output response captured by the memory elements is always the same for a given test pattern and the signature register always generates the same signature. However, there are circumstances where the output response is not completely predictable and repeatable and yet it is desired to compute a signature to analyze the part of the output response that is predictable and repeatable. A non-repeatable output response can be caused by test patterns that are not valid functional patterns or by a design error or a defect. Whatever the reason, the corrupted bits (each memory element in a scan chain stores one bit of the output response) must be masked so that the signature register can generate a repeatable signature for a “good circuit”, i.e., a circuit that is good except for some logic that generated corrupted bits.

Typically, corrupted bits are masked prior to applying them to the input of the signature register. However, some corrupted bits in the output response may not be caused by defective logic circuits. Rather, they may be caused by incorrect operation of one or more scan chains. The incorrect operation could be caused by a blockage of the scan data or scan data being lost because of a hold time problem. In the latter case, the serial input of the defective scan chains can be masked.

Applicants' U.S. Pat. No. 6,745,359 issued on Jun. 1, 2004 for “Method of Masking Corrupt Bits During Signature Analysis and Circuit for Use Therewith” (Docket No. LVPAT060US), incorporated herein by reference, discloses and claims a masking circuit for use in masking bits in scan chains in an integrated circuit under test. The masking circuit comprises a scan chain mask register for storing a scan chain mask and a bit position mask register for storing a position mask. The chain mask register has chain mask register elements with each of the elements being associated with one or more scan chains and identifying scan chains in which bits are to be masked. The position mask register has position mask register elements, each of which stores a position mask bit which identifies scan chain bit positions to be masked. A gating circuit has a scan chain input for each scan chain connected to the serial output of the scan chains, a bit position mask input connected to bit position mask register, a chain mask input connected to the chain mask register, a first coupling means for coupling the position and chain mask inputs and generating a masking bit and second coupling means for coupling the masking bit with a serial output of each of the scan chains. The circuit described does not provide any means for handling defective scan chains or the loss of data caused by hold time problems.

Abdel-Hafez et al. U.S. patent application Ser. No. 20040237015 published on Nov. 25, 2004 discloses a method and circuit which uses an output mask controller and network and an input chain-mask controller and an input-mask network. The latter is to allow designers to recover from faulty scan chain design by forcing constant logic values to the scan chain inputs of failing scan chains during test. The input mask network is controlled by an input chain-mask controller. The input chain-mask controller generates input-mask enable signals. The input chain-mask controller is programmed through a Chain-Mask-In input when a Load signal is asserted. In one embodiment, the input chain-mask controller consists of a shift register comprised of a number of storage elements. The number of storage elements matches the number of scan chains in a scan core. The output of the shift register specifies input-mask enable information for all scan chains in parallel. An embodiment of the input-mask network consists of a number of OR gates, one for each scan chain input. Input-mask enable signals are ORed with scan chain inputs and the outputs drive the internal scan chain inputs. In this embodiment, a scan chain input is blocked if its corresponding input-mask enable signal is set to logic value 1. Another embodiment of the input-mask network consists of a number of AND gates, one for each scan chain input. Input-mask enable signals are ANDed with scan chain inputs and the outputs drive the internal scan chain inputs. In this embodiment, a scan chain input is blocked, if its corresponding input-mask enable signal is set to logic value 0.

Similar circuitry is provided for masking scan chain outputs. The invention suffers from the drawback that the input and output mask controllers are relatively complex and require considerable circuit resources.

Rajski et al. U.S. Pat. No. 6,829,740 issued on Dec. 7, 2004 for “Method and Apparatus for Selectively Compacting Test Responses” discloses a method and apparatus to compact test responses containing unknown values or multiple fault effects in a deterministic test environment. The proposed selective compactor employs a linear compactor with selection circuitry for selectively passing test responses to the compactor. In one embodiment, gating logic is controlled by a control register, a decoder, and flag registers. This circuitry, in conjunction with any conventional parallel test-response compaction scheme, allows control circuitry to selectively enable serial outputs of desired scan chains to be fed into a parallel compactor at a particular clock rate. A first flag register determines whether all, or only some, scan chain outputs are enabled and fed through the compactor. A second flag register determines if the scan chain selected by the selector register is enabled and all other scan chains are disabled, or the selected scan chain is disabled and all other scan chains are enabled.

The drawbacks to this arrangement are that it focuses on diagnosis only and does not provide masking modes to maximize fault coverage in the presence of unknowns. Also, the arrangement does not address problems associated with hold time which require to masking both scan chain inputs and scan chain outputs.

### SUMMARY OF THE INVENTION

The present invention seeks to improve on prior art masking circuitry in a manner which maximizes the fault coverage of a test, minimizes the amount of additional logic required to implement mask circuitry, minimizes the number of clock cycles required to perform a test, maximizes the clock rate at which a signature can be computed, minimizes the amount of information which needs to be stored on a tester and provides a default mode of operation which does not require any information from the tester.

More specifically, the present invention seeks to provide masking circuitry which is of simple construction and which selectively provides for masking of the output or input and output of any scan chain. The invention provides a mask register which has at least two register elements associated with each scan chain and a mask control circuitry which responds to the contents of the register elements to provide one of a plurality of masking modes for each scan chain. In one embodiment, the mask register comprises a one-bit register element for each scan chain to specify whether the output of a scan chain is to be masked and a global one-bit register element, which is common to all scan chains, to specify whether the scan chain input of scan chains whose outputs are to be masked, will also be masked. This provides for three masking modes: no masking of a scan chain; masking of all outputs of a scan chain, and masking of both all inputs and all outputs of a scan chain.

In another embodiment, a two-bit register is provided for each scan chain. The register determines whether input and/or output masking is to be performed on the corresponding scan chain and provides for four masking modes for each scan chain. In this embodiment, a position mask determines the mask value to be applied when specific cells of a scan chain are to be masked.

These features allow at-speed production tests or field tests to be performed while maximizing fault coverage.

### BRIEF DESCRIPTION OF THE DRAWINGS

These and other features of the invention will become more apparent from the following description in which reference is made to the appended drawings in which:

FIG. 1 is a block diagrammatic view of a gating circuit according to one embodiment of the present invention;

FIG. 2 is a circuit schematic view according to one embodiment of a gating circuit of the embodiment of FIG. 1;

FIG. 3 is a circuit schematic view of according to a second embodiment of the present invention;

FIG. 4 is a circuit schematic view of according to a third embodiment of the present invention;

FIG. 5 is a schematic view of scan chain input masking circuit according to the embodiment of FIG. 4; and

FIG. 6 is a schematic view of scan chain output masking circuit according to the embodiment of FIG. 4.

### DETAILED DESCRIPTION OF EMBODIMENTS OF THE INVENTION

In the following detailed description, numerous specific details are set forth in order to provide a thorough understanding of the present invention, However, it will be understood by those skilled in the art that the present invention may be practiced without these specific details. In other instances, well known methods, procedures, components and circuits have not been described in detail so as not to obscure aspects of the present invention.

In general, the present invention provides a masking circuit for selectively masking scan chain outputs and inputs during scan testing of an integrated circuit. The masking circuit comprises a mask register having at least two mask register elements for each scan chain to provide a plurality of masking modes; and an input and output mask control circuit for each scan chain. Each of the mask control circuits is connected between a test pattern source and a signature register and between a serial input and a serial output of an associated scan chain and is responsive to mask control data stored in the register elements for configuring the associated scan chain in one of the plurality of masking modes during a scan test of the circuit.

One embodiment of the present invention seeks to provide a masking circuit which is of simple construction and of a small size. The masking circuit is incorporated into a logic test controller. The at least two register elements include a scan chain specific register element for each scan chain for storing mask control data that selectively indicates whether the output of its corresponding scan chain is to be masked; and a global register element that is common to all scan chains for storing mask control data indicating whether the input of a scan chain is to be masked if the mask control data stored in the specific register element of the scan chain indicates that the scan chain output is to be masked.

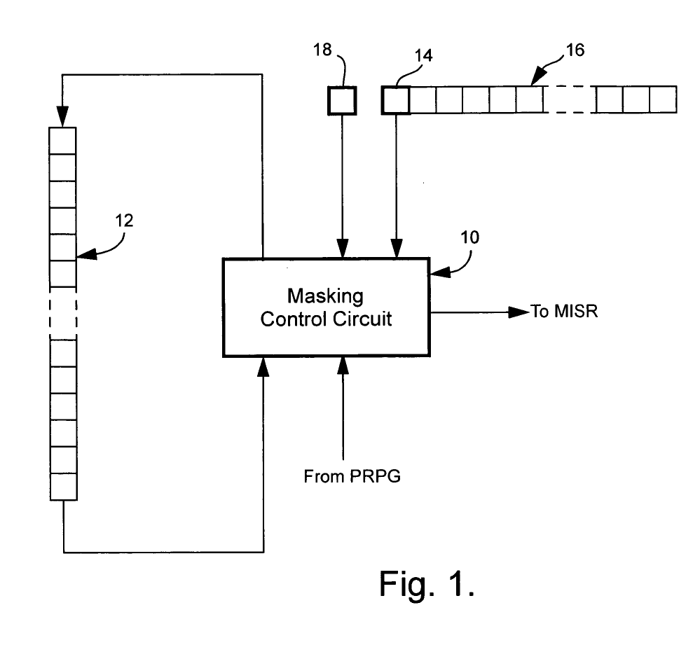

As shown in FIG. 1, masking circuit 10 is connected to both the input and output of a corresponding scan chain 12, a scan chain output mask bit 14 of a scan chain mask register 16, a scan chain input mask bit 18, a test pattern source, such as a pseudo-random pattern generator, (PRPG), not shown, and a multiple input signature register (MISR), not shown. To simplify the description and drawings, only one mask control circuit is shown. However, it will be understood that a mask control circuit is provided for each scan chain.

The scan chain output mask bit determines whether the output of the scan chain is to be masked. One value (e.g., Logic 0) of the scan chain mask bit indicates that the output of the scan chain is not to be masked. Another value (e.g., Logic 1) of the scan chain mask bit indicates that all timeslots of the scan chain output are to be gated to Logic 0. The scan chain input mask bit is applied to the mask control circuit of all of the scan chains. One value (e.g., Logic 0) indicates that the input of the scan chain is not to be masked. Another value (e.g., Logic 1) indicates that all timeslots (scan cells) of the scan chain input of a scan chain whose outputs are to be masked, is to be gated to a predetermined value, e.g., Logic 0.

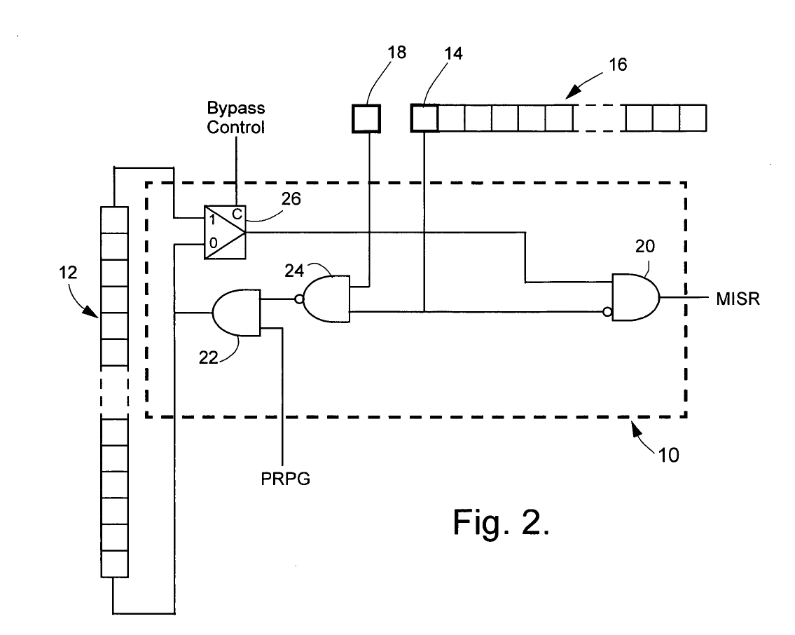

FIG. 2 illustrates a specific embodiment of masking circuit 10 as being comprised of three gates, including AND gates 20 and 22, a NAND gate 24, and a bypass multiplexer (mux) 26. The output of AND gate 20 is connected to an input of the MISR. An inverted input of gate 20 is connected to the scan chain mask bit and the other input is connected to the output of mux 26. Mask bit 18 serves as a global input mask bit. Mask bit 18 and scan chain mask bit 14 are connected to respective inputs of NAND gate 24 whose output is connected to one input of AND gate 22. The other input of AND gate 22 is connected to a PRPG. The output of gate 22 is connected to the input of the associated scan chain 12 and to one input of bypass mux 26. The output of the scan chain is connected to the other input of bypass mux 26. The mux is controlled by a bypass control signal which bypasses the chain path when an associated BIST controller is not enabled or when the BIST controller is in a controller TestMode. This will eliminate many STA (Static-timing analysis) and synthesis problems in functional mode. TABLE A outlines the effect of various bit combinations of bits 18 and 14.

TABLE A

| | | |
|---|---|---|
| Value | Name | Description |

Scan Chain Output Mask Bit 14

| | | |
|---|---|---|
| 0 | Normal | No masking of the output of the corresponding |
| | | scan chain. |
| 1 | Output | Gate to 0 all time slots of the output of the |
| | | corresponding scan chain. |

Global Scan Chain Input Mask Bit 18

| | | |
|---|---|---|
| 0 | Output | No masking of scan chain inputs. |
| 1 | InputOutput | Gate to 0 all time slots of scan chain inputs of |
| | | scan chains that have their output masked. |

It will be seen that no masking is performed when both output mask bit 14 and input mask bit 18 are set to logic 0. When output mask bit 14 is asserted for a scan chain, all serial outputs (timeslots) of the scan chain are gated to logic 0 and that when input mask bit 18 is asserted, the serial input is similarly gated to Logic 0 for all scan chains whose corresponding mask bit 14 is asserted.

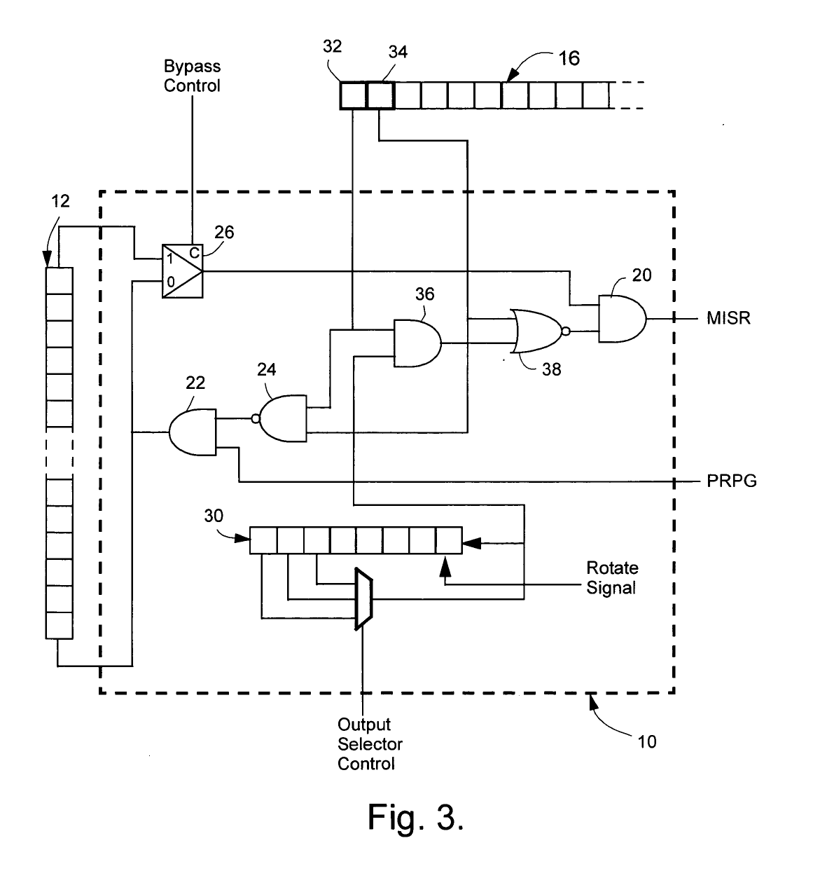

FIG. 3 illustrates a second embodiment of the present invention. This embodiment is similar to that of FIG. 2 and, accordingly, the same reference numerals have been used for the same components. In this embodiment, two scan chain specific, mask register elements are provided for each scan chain. This allows any one or more scan cells of any scan chain to be masked.

This embodiment of the invention includes a position mask 30 in addition to chain mask 16. The position mask outputs a bit value which is used to mask the contents of a cell in a scan chain which is marked to be masked by an associated chain mask bit in the chain mask. This is similar to the invention of Applicants' aforementioned patent; however, there are two primary differences.

First, each scan chain is associated with at least two bits of the chain mask as mentioned above. Second, both the serial input and the serial output of a scan chain can be masked selectively. Thus, in FIG. 3, register elements 32 and 34 in mask register 16 are associated with an predetermined scan chain, such as scan chain 12. The two register elements 32 and 34 provide a two-bit mask code which yields four possible masking modes for masking the serial output and serial input of a scan chain. In this embodiment, the output of register element 32 is applied to one input of AND gate 36 and of NAND gate 24. The output of register element 34 is applied to one input of NOR gate 38 and the other input of NAND gate 24. AND gate 36 receives the output of position register 30 and provides an output to the other input of NOR gate 38. The output of NOR gate 38 is applied to an input of AND gate 20, as shown, whose output is applied to the MISR. TABLE B outlines the bit combinations and corresponding masking modes.

Mask register 16 is in the form of a shift register which includes both register elements 32 and 34 of all scan chains, as shown. It will be understood that the mask register may be arranged in the form of two shift registers (not shown), one containing all register elements 32 and the other containing all register elements 34.

TABLE B

| Mode | Bits | Description |
|---|---|---|
| 1 | 00 | No masking of either the serial input or the serial output. |
| 2 | 10 | Gate to 0 the scan chain cells indicated by the position |
| | | mask. |
| 3 | 01 | Gate to 0 all outputs of the associated scan chain. |
| 4 | 11 | Gate to 0 all input and output time slots of the associated |
| | | scan chain (This mode useful for hold time problem in |
| | | scan path.) |

Mode 1 and Mode 2 are the same as those provided in Applicant's aforementioned patent, i.e. they provide for either no masking of a scan chain or masking of selected cells of a scan chain.

Mode 3 provides for masking of all output timeslots of a scan chain and Mode 4 provides for masking of all input and output timeslots of a scan chain.

Mode 3 improves fault coverage in two situations. The first situation is one in which there is a problem with a scan chain which requires that its data be masked in all positions. Normally, in this situation, all scan chains that only have a few positions with corrupted bits would need to be masked completely because the same position mask is used for all chains. However, configuring scan chains which require masking of their entire output response using Mode 3 allows for the use of the position mask for other scan chains that only have a few corrupted bits.

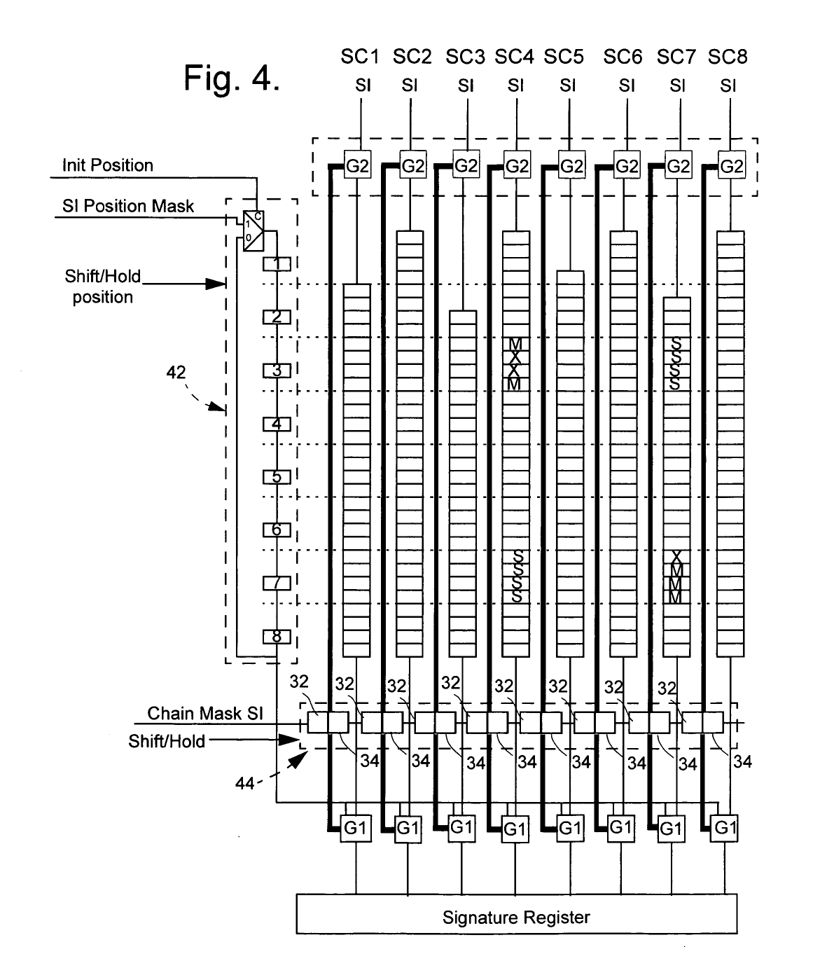

The second situation in which fault coverage can be increased is by using multiple test steps in which each test step uses a chain mask that unconditionally masks all scan chains having corrupted bits except for one scan chain which is conditionally masked using the position mask (Mode 2). This will be better understood by reference to FIG. 4.

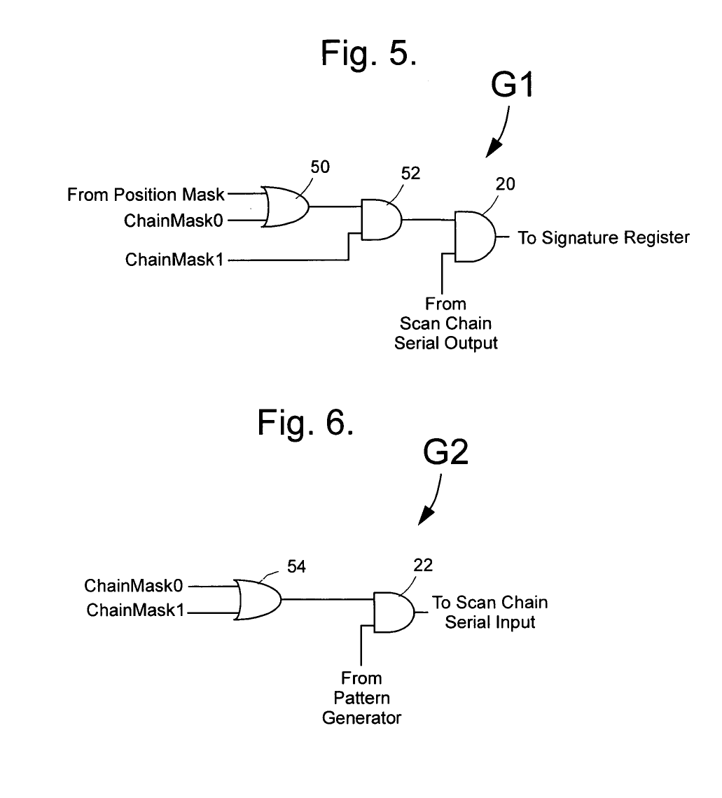

FIG. 4 shows eight scan chains labeled SC1 through SC8, with scan chains SC4 and SC7 having corrupted bits. The figure shows a position mask register 42 and a chain mask register 44. Register 44 is provided with two register elements for each scan chain, as previously described in the embodiment of FIG. 3. Each scan chain is provided with an output mask control circuit labeled G1, illustrated in detail in FIG. 5, which receives the serial output of its associated scan chain, the output of the position mask, and the output of its two chain mask register elements, and an input mask control circuit labeled G2, illustrated in detail in FIG. 6, which receives an input, S1, from a pattern generator, and the output of its two chain mask register elements, and which provides an output to the serial input of its associated scan chain. The position mask register operates in the manner described in Applicants' aforementioned patent and, accordingly, the operation is not repeated herein.

Scan cells marked with an “X” are corrupted bits. Cells marked with an “M” are masked in addition to cells marked with X when the resolution of the position mask is less than one scan cell. Scan cells marked with “S” are masked if a test is run in a single step and the position mask is used to mask corrupted bits of both scan chains SC4 and SC7, using Mode 2.

However, using Mode 3 and applying a test in two steps allows the output response of the scan cells marked with an S to be examined. This increases test coverage. In the first step, chain SC4 is unconditionally masked using Mode 3 and chain SC7 is masked using Mode 2, allowing cells to be masked using the position mask. In the second step, Mode 3 is used to unconditionally mask all outputs of chain SC7 and Mode 2 is used to mask cells in chain SC4 using the position mask.

FIG. 5 and FIG. 6 illustrate output and input mask control circuits G1 and G2, respectively, in more detail. Referring to FIG. 5, control circuit G1 associated with the serial output of a scan chain and is comprised of an OR gate 50 and an AND gate 52. The OR gate receives the output of the position mask and the output of one of the scan chain register elements, labeled ChainMask0 in the figure. The output of the OR gate is applied to one input of AND gate 52. The output, labeled ChainMask1, of the other of the chain register elements, is applied to the other input of AND gate 52. It will be seen that the serial output is unconditionally masked if scan chain bit labeled ChainMask1 is Logic 0. This forces the outputs of both AND gates to Logic 0 and occurs when either Mode 3 or Mode 4 is applied to a particular chain.

If ChainMask1 is Logic 1 (as in Mode 1 and Mode 2), masking depends on the state of ChainMask0. If ChainMask0 is Logic 0 (Mode 2), the position mask determines the bits to be masked. If ChainMask0 is Logic 1 (Mode 1), then the position mask has no influence on masking.

Mask control circuit G2 of the serial input, shown in FIG. 6, simply comprises an OR gate 54 and AND gate 22. OR gate 54 receives the output of each of the two mask register elements associated with a scan chain. It will be seen that if both ChainMask1 and ChainMask0 are Logic 0, the serial input is forced to a constant value. In the implementation shown in FIG. 6, a value of Logic 0 is forced on the serial input and the serial output. However, it will be understood that the value could be Logic 1. Also, the code assignment for ChainMask1 and ChainMask0 could differ. These variations would be obvious to a person skilled in the art.

All of the default modes of operation described in Applicants' prior patent, supra, are applicable to the method described herein. The explanation of these modes is not repeated herein.

Although the present invention has been described in detail with regard to preferred embodiments and drawings of the invention, it will be apparent to those skilled in the art that various adaptions, modifications and alterations may be accomplished without departing from the spirit and scope of the present invention. Accordingly, it is to be understood that the accompanying drawings as set forth hereinabove are not intended to limit the breadth of the present invention, which should be inferred only from the following claims and their appropriately construed legal equivalents.

1. A masking circuit for selectively masking scan chain inputs and/or outputs during scan testing of an integrated circuit, comprising:
a mask register having at least two mask register elements for each scan chain to provide a plurality of masking modes; and
an input and output mask control circuit for each scan chain, each said mask control circuit being connected between a test pattern source and a signature register and between a serial input and a serial output of an associated scan chain and being responsive to mask control data stored in said register elements for configuring said associated scan chain in one of said plurality of masking modes during a scan test of said circuit.

2. A masking circuit as defined in claim 1, said at least two register elements including:
a scan chain specific register element for each scan chain for storing mask control data for selectively indicating whether the output of its corresponding scan chain is to be masked; and
a global register element common to all scan chains for storing mask control data for indicating whether the input of a scan chain is to be masked if the mask control data stored in the specific register element of the scan chain indicates that the scan chain output is to be masked.

3. A masking circuit as defined in claim 2, said masking modes including:
a first mode in which no scan cells in an associated scan chain are masked;
a second mode for masking the output of a scan chain whose respective specific register element stores a predetermined mask control data value; and
a third mode for masking the scan chain input and the scan chain output of a scan chain when the scan chain specific register element and said global register element store respective predetermined mask control data values.

4. A masking circuit as defined in claim 3, wherein mask data is a logic 0.

5. A masking circuit as defined in claim 1, each said mask control circuit including:
first means for receiving the output of said global register element and said scan chain specific register element, said first means producing an inactive output when the outputs of said register elements correspond to predetermined values and otherwise producing an active output; and
second means responsive to said active output of said first means for applying said test pattern source to the serial input of the scan chain associated with said mask control circuit and responsive to said inactive output for applying a predetermined value to the input of the scan chain associated with said mask control circuit; and
third means responsive to the inverted output of said scan chain specific register element and one of the serial input or serial output of the corresponding scan chain to produce an output applied to said signature register.

6. A masking circuit as defined in claim 5, further including bypass selector means responsive to a control signal for selecting between said one of the serial input or serial output of said corresponding scan chain and applying a selected output to an input of said third means.

7. A masking circuit as defined in claim 1, said mask register having a pair of specific register elements for each scan chain.

8. A masking circuit as defined in claim 7, said masking modes including:
a first mode in which no scan cells are masked in the scan chain associated with a pair of register elements;
a second mode for setting to a predetermined mask value the contents of predetermined scan chain cells of a scan chain associated with a pair of register elements;
a third mode for setting to a predetermined mask value the value of all outputs of a scan chain; and
a fourth mode for setting to a predetermined mask value all inputs and outputs of a scan chain associated with a corresponding pair of specific register elements.

9. A masking circuit as defined in claim 8, said predetermined mask value is a logic 0.

10. A masking circuit as defined in claim 8, each said mask control circuit including:
circuit means responsive to a first combination of data bit values in said pair of specific register elements for providing said first masking mode;
circuit means responsive to a second combination of data bit values in said specific pair of register elements for providing said second masking mode;
circuit means responsive to a third combination of data bit values in said pair of specific register elements for providing said third masking mode; and
circuit means responsive to a fourth combination of data bit values in said pair of specific register elements for providing said fourth masking mode.

11. A method for selectively masking scan chain inputs and/or outputs during scan testing of an integrated circuit, comprising:
assigning a masking control bit to each of at least two register elements, associated with each scan chain, in a masking register in said integrated circuit so as to specify a masking mode for each scan chain; and
performing a scan test.

12. A method as defined in claim 11, said masking mode for each scan chain including one of:
a first mode in which no scan cells of an associated scan chain is masked;
a second mode for setting selected scan cells of an associated scan chain to a predetermined mask value;
a third mode for setting the value of all outputs of a scan chain to a predetermined value; and
a fourth mode for setting all inputs and outputs of a scan chain a predetermined mask value.

13. A method as defined in claim 11, said masking mode for each scan chain including one of:
a first mode in which no scan cells of an associated scan chain is masked;
a second mode for setting all outputs of a scan chain to a predetermined mask value; and
a third mode for setting to a predetermined mask value the scan chain input of scan chains whose output is to be masked.

14. A method of performing a scan test on a circuit having a plurality of scan chains with one or more of said scan chains having corrupted bits, said circuit having a masking register consisting of at least two register elements for each scan chain to provide a plurality of masking modes, said method comprising:
(a) configuring all but one of said scan chains having corrupted bits in a first masking mode which unconditionally masks the input and/or output of the scan chain;
(b) configuring in a second masking mode one scan chain for conditionally masking predetermined cells in said one scan chain;
(c) configuring in a third mode scan chains which do not have corrupted bits;
(d) repeating steps (a) to (c) in which another scan chain of said plurality of scan chains is used as said one scan chain.

15. A method as defined in claim 14, said configuring comprising setting said at least two register elements of each scan chain to provide an appropriate masking mode for each scan chain.

16. A method of scan testing a circuit having a plurality of scan chains with one or more scan chains having corrupted bits including scan chains which require masking of all cells, said circuit having a position mask for masking predetermined scan cells and a masking register consisting of at least two register elements for each scan chain to provide a plurality of masking modes, said method comprising:
configuring scan chains having no corrupted bits in a first mode;
configuring in a second mode scan chains which require masking of either all respective scan chain outputs or all respective scan chain inputs and outputs; and
configuring in a third mode scan chains all scan cells which only required masking of corrupted scan cells according to said position mask.
